(19) United States
(12) Patent Application Publication
(10) Pub. No.: US 2025/0069984 A1
(43) Pub. Date: Feb. 27, 2025

(54) POWER SEMICONDUCTOR DEVICE AND POWER ELECTRONICS ASSEMBLY

(71) Applicant: Infineon Technologies Austria AG, Neubiberg (DE)

(72) Inventor: Ralf Otremba, Kaufbeuren (DE)

(21) Appl. No.: 18/454,258

(22) Filed: Aug. 23, 2023

(51) Int. Cl. H01L 23/373; H01L 23/31; H01L 23/495; H01L 25/10

(52) U.S. Cl. CPC H01L 23/3735; H01L 23/3107; H01L 23/49575; H01L 25/105

(57) ABSTRACT

A power semiconductor device includes a molded package and an insulated metal substrate (IMS). The molded package includes one or more power semiconductor dies embedded in a mold compound and forming part of a power electronics circuit A metallic region exposed at a topside of the molded package forms part of a primary thermal pathway for heat dissipated by the one or more power semiconductor dies during operation. The IMS includes a copper layer attached to the metallic region exposed at the topside of the molded package, an aluminum layer at an opposite side of the IMS as the copper layer, and an organic isolation layer that electrically isolates the copper layer and the aluminum layer from one another. The copper layer provides no electrical rerouting for the molded package. A power electronics assembly including a plurality of the power semiconductor devices mounted to a circuit board is also described.

### BACKGROUND

High power semiconductor applications such as main inverters, battery management systems, on-board chargers, etc. typically require 100 to 1,000 mm² chip area just for one device such as a MOSFET (metal-oxide-semiconductor field-effect transistor) or IGBT (insulated gate bipolar transistor) with a maximum current in the range of 100 to 1,000 Amps and/or power losses in the range of 100 to 1,000 Watts. To accommodate such requirements, conventional power modules which include several power semiconductor dies attached to a DBC (direct bonded copper) or AMB (active metal brazed) substrate are likely to be replaced by parallelized molded power devices for improved cost and performance at the system level. However, adequate thermal redistribution presents a pressing problem for parallelized molded power devices.

Thus, there is a need for an improved power semiconductor device for high power applications.

### SUMMARY

According to an embodiment of a power semiconductor device, the power semiconductor device comprises: a molded package comprising one or more power semiconductor dies embedded in a mold compound and forming part of a power electronics circuit, wherein a metallic region exposed at a topside of the molded package forms part of a primary thermal pathway for heat dissipated by the one or more power semiconductor dies during operation; and an insulated metal substrate (IMS) comprising a copper layer attached to the metallic region exposed at the topside of the molded package, an aluminum layer at an opposite side of the IMS as the copper layer, and an organic isolation layer that electrically isolates the copper layer and the aluminum layer from one another, wherein the copper layer provides no electrical rerouting for the molded package.

According to an embodiment of a power electronics assembly, the power electronics assembly comprises: a circuit board; a plurality of power semiconductor devices mounted to the circuit board and each comprising: a molded package comprising one or more power semiconductor dies embedded in a mold compound and forming part of a power electronics circuit, wherein a metallic region exposed at a side of the molded package that faces away from the circuit board forms part of a primary thermal pathway for heat dissipated by the one or more power semiconductor dies during operation; and an insulated metal substrate (IMS) comprising a copper layer attached to the metallic region exposed at the side of the molded package that faces away from the circuit board, an aluminum layer at an opposite side of the IMS as the copper layer, and an organic isolation layer that electrically isolates the copper layer and the aluminum layer from one another, wherein the copper layer provides no electrical rerouting for the molded package; a thermal interface material applied to the aluminum layer of each IMS; and a cooling system thermally connected to each IMS through the thermal interface material.

Those skilled in the art will recognize additional features and advantages upon reading the following detailed description, and upon viewing the accompanying drawings.

### BRIEF DESCRIPTION OF THE FIGURES

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1 illustrates a side view of a power semiconductor device that includes a molded package and an insulated metal substrate (IMS).

FIG. 2 illustrates a side view of the power semiconductor device, according to another embodiment.

FIGS. 3A and 3B illustrate top and bottom perspective views, respectively, of an embodiment of the molded package included in the power semiconductor device.

FIG. 4A illustrates a side view and FIGS. 4B and 4C illustrate front and back perspective views, respectively, of another embodiment of the power semiconductor device.

FIG. 5 illustrates a side view of a power electronics assembly that includes a plurality of the power semiconductor devices mounted to a circuit board, according to an embodiment.

### DETAILED DESCRIPTION

The embodiments described herein provide a power semiconductor device and corresponding power electronics assembly for high power applications. The power semiconductor device provides adequate thermal redistribution and is well-suited for high power applications such as main inverters, battery management systems, on-board chargers, etc. The power semiconductor device includes a molded package with one or more power semiconductor dies embedded in a mold compound. A metallic region is exposed at the topside of the molded package and forms part of a primary thermal pathway for heat dissipated by the one or more power semiconductor dies during operation. The power semiconductor device also includes an insulated metal substrate (IMS) instead of a more expensive DBC or AMB substrate.

A copper layer of the IMS is attached to the metallic region exposed at the topside of the molded package. The IMS also has an aluminum layer at the opposite side of the IMS as the copper layer. An organic isolation layer of the IMS electrically isolates the copper layer and the aluminum layer from one another. The copper layer of the IMS provides no electrical rerouting (redistribution) for the molded package. Accordingly, the copper layer of the IMS forms part of the primary thermal pathway for heat dissipated by the one or more power semiconductor dies during operation, but does not reroute or redistribute the primary current pathway of the power semiconductor device.

Multiple instances (e.g., dozens or more) of the power semiconductor device may be included in the same power electronics assembly for use in a high power application, e.g., where the maximum current is in a range of 100 to 1,000 Amps and/or power losses are in a range of 100 to 1,000 Watts. The power semiconductor devices are mounted to a circuit board such as a controller board. The power electronics assembly also includes a thermal interface material applied to the aluminum layer of each IMS, and a cooling system thermally connected to each IMS through the thermal interface material.

During production of the power electronics assembly, metallic debris such as Cu (copper) and/or Al (aluminum) particles/burrs may become trapped between the cooling system and one or more of the power semiconductor devices. If this were to occur, the combined thickness of the thermal interface material and the aluminum layer of each IMS is greater than the thickness of the metallic debris such that the metallic debris is confined outside the organic isolation layer of each IMS. Accordingly, the metallic debris may penetrate the thermal interface material and possibly even the aluminum layer of at least one IMS but not the organic isolation layer of any IMS. This ensures that the organic isolation layer of each IMS remains fully intact and uncompromised by the metallic debris, which in turn ensures the copper layer of each IMS remains electrically isolated from the cooling system. By using IMS instead of more expensive DBC or AMB substrates, overall system cost is reduced while still enabling top-side cooling for each power semiconductor device.

Described next, with reference to the figures, are exemplary embodiments of the power semiconductor device and corresponding power electronics assembly for high power applications.

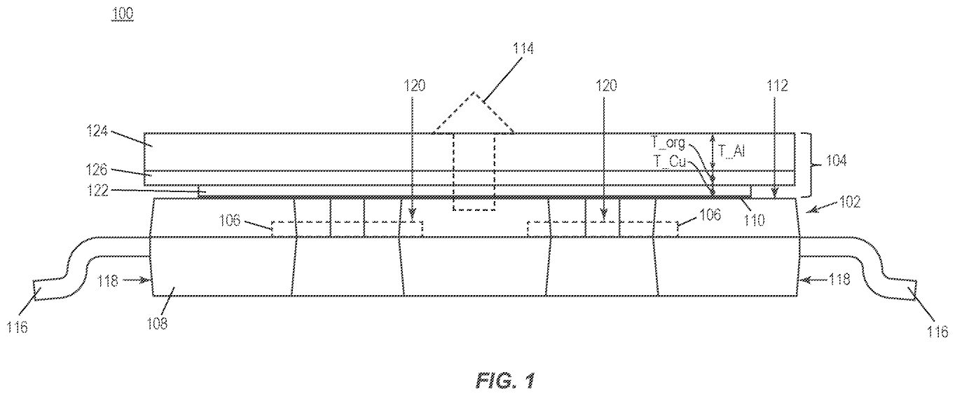

FIG. 1 illustrates a side view of a power semiconductor device 100. The power semiconductor device 100 includes a molded package 102 and an insulated metal substrate (IMS) 104. The molded package 102 includes one or more power semiconductor dies (chips) 106 embedded in a mold compound 108. The mold compound 108 is a plastic encapsulant typically formed from an organic resin such as an epoxy resin. The plastic encapsulant may include fillers such as non-melting inorganic materials. Catalysts may be used to accelerate the cure reaction of the organic resin. Other materials such as flame retardants, adhesion promoters, ion traps, stress relievers, colorants, etc. may be added to the plastic encapsulant, as appropriate.

The one or more power semiconductor dies 106 embedded in the mold compound 108 form part of a power electronics circuit such as a DC/AC inverter, a DC/DC converter, an AC/DC converter, a DC/AC converter, an AC/AC converter, a multi-phase inverter, an H-bridge, etc. One or more of the power semiconductor dies 106 may be a power transistor die, a power diode die, a half bridge die, etc., or a die that combines logic and power devices on the same semiconductor substrate. In one embodiment, at least one of the semiconductor dies 106 is a power transistor die such as a power Si MOSFET die, an IGBT die, a SIC MOSFET die, a GaN HEMT (high electron mobility transistors) die, etc. Each power semiconductor die 106 is obstructed by the mold compound 108 in the view of FIG. 1 and therefore illustrated using a dashed rectangle.

A metallic region 110 exposed at the topside 112 of the molded package 102 forms part of a primary thermal pathway 114 for heat dissipated by the power semiconductor die(s) 106 during operation. Accordingly, the metallic region 110 exposed at the topside 112 of the molded package 102 enables topside cooling of the power semiconductor device 100. The metallic region 110 may terminate above, below, or be coplanar with the topside 112 of the molded package 102. The primary current pathway of the power semiconductor device 100 is through leads 116 that protrude through one or more side faces 118 of the mold compound 108. The primary current pathway may include the metallic region 110 exposed at the topside 112 of the molded package 102, depending on the type of power semiconductor die(s) 106 used and the interconnections within the molded package 102.

The leads 116 of the molded package 102 may be part of a metallic lead frame, with the power semiconductor die(s) 106 being attached to another part (out of view) of the metallic lead frame. In the case of vertical power semiconductor die(s) 106, the metallic region 110 exposed at the topside 112 of the molded package 102 may be at a high electric potential such as drain potential in the case of a power MOSFET, collector potential in the case of an IGBT, or anode potential in the case of a power diode.

The metallic region 110 exposed at the topside 112 of the molded package 102 may comprise a single layer of metal or metal alloy or a stack of two or more layers of metal or metal alloys. For example, the metallic region 110 may be part of a metallic lead frame or clip frame that is attached to the topside 120 of the power semiconductor die(s) 106 and exposed at the topside 112 of the molded package 102.

The IMS 104 included in the power semiconductor device 100 comprises a copper layer 122 attached to the metallic region 110 exposed at the topside 112 of the molded package 102. For example, the copper layer 122 of the IMS 104 may be glued, soldered, or welded to the metallic region 110 exposed at the topside 112 of the molded package 102.

The IMS 104 also includes an aluminum layer 124 at the opposite side of the IMS 104 as the copper layer 122. An organic isolation layer 126 such as epoxy, polyimide, etc. electrically isolates the copper layer 122 and the aluminum layer 124 from one another, such that the copper layer 122 provides no electrical rerouting or redistribution for the molded package 102.

In one embodiment, the aluminum layer 124 of the IMS 104 has a thickness T_Al in a range of 0.5 mm to 5 mm and the organic isolation layer 126 of the IMS 104 has a thickness T_org in a range of 5 μm to 250 μm. The copper layer 122 of the IMS 104 may have a thickness T_Cu in a range of 35 μm to 350 μm. The organic isolation layer 126 of the IMS 104 may have a thermal conductivity less than 1 W/K at 300 K.

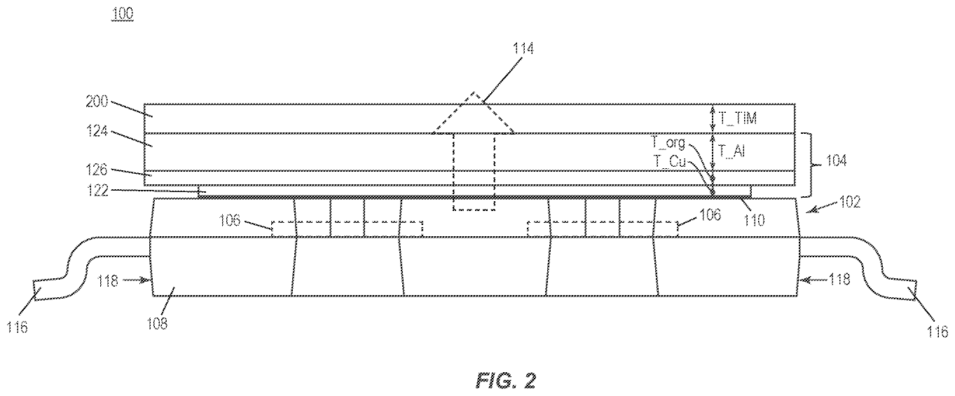

FIG. 2 illustrates a side view of the power semiconductor device 100, according to another embodiment. In FIG. 2, the power semiconductor device 100 further includes a thermal interface material 200 applied to the aluminum layer 124 of the IMS 104. The thermal interface material 200 may be a thermal tape, grease, gel, adhesive, sinter layer, dielectric pad, phase change material (PCM), etc. The thermal interface material 200 may include fillers such as non-melting inorganic materials. In one embodiment, the aluminum layer 124 of the IMS 104 is thicker than the thermal interface material 200. Separately or in combination, the thickness T_Al of the aluminum layer 124 of the IMS 104 may be in a range of 0.5 mm to 5 mm and the thermal interface material 200 may have a thickness T_TIM in a range of 100 μm to 500 μm.

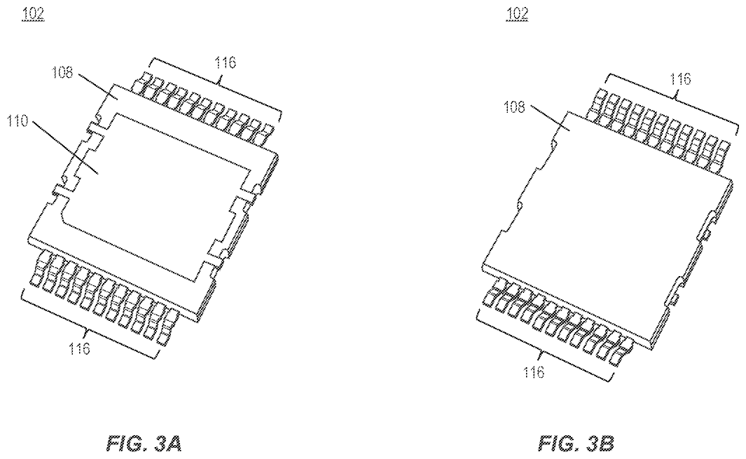

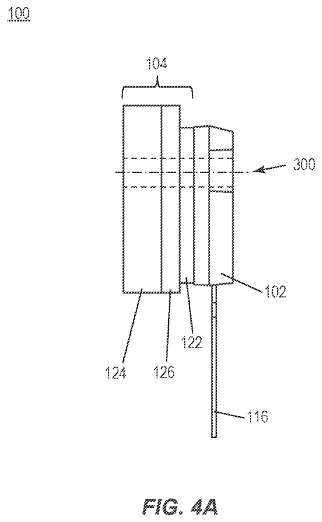

FIGS. 3A and 3B illustrate top and bottom perspective views, respectively, of an embodiment of the molded package 102 included in the power semiconductor device 100. In FIGS. 3A and 3B, the molded package 102 is a surface mount package. A surface mount package is a package that is mounted onto the surface of a printed circuit board (PCB) via the leads 116 of the molded package 102. The PCB is not shown in FIGS. 3A and 3B to provide an unobstructed view of the molded package 102.

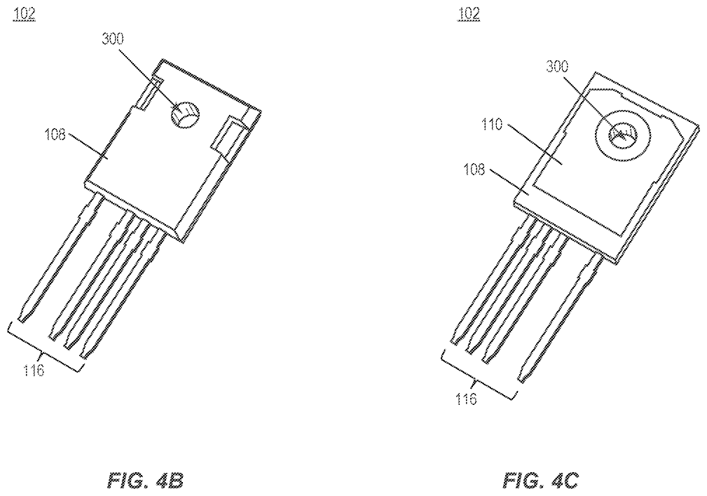

FIG. 4A illustrates a side view and FIGS. 4B and 4C illustrate front and back perspective views, respectively, of another embodiment of the power semiconductor device 100. The IMS 104 is not shown in FIGS. 4B and 4C to provide an unobstructed view of the molded package 102. In FIGS. 4A to 4C, the molded package 102 is a through-hole mount package. A through-hole mount package is a package that is mounted by inserting the package leads 116 through holes drilled in a PCB and soldered to pads on the opposite side of the PCB. The PCB is not shown in FIGS. 4A to 4C to provide an unobstructed view of the power semiconductor device 100 (FIG. 4A) and the molded package 102 (FIGS. 4B and 4C). The IMS 104 may be mounted to a heat sink, e.g., by a fastener inserted through a hole/opening 300 that extends through both the molded package 102 and the IMS 104 of the power semiconductor device 100.

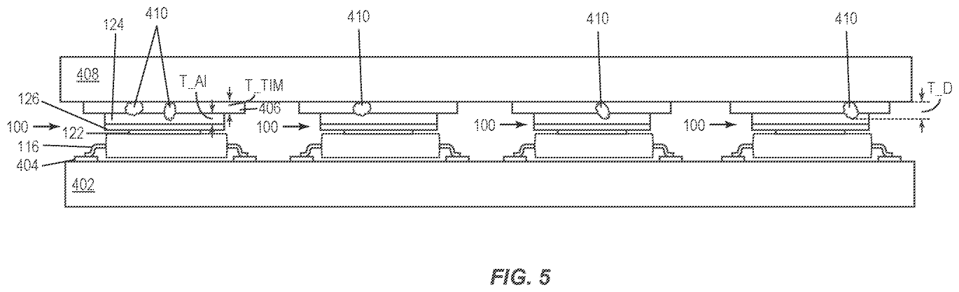

FIG. 5 illustrates a side view of a power electronics assembly 400 that includes a plurality of the power semiconductor devices 100 mounted to a circuit board 402, according to an embodiment. The power electronics assembly 400 is designed for use in high power applications such as main inverters, battery management systems, on-board chargers, etc. Dozens or more (e.g., 50 or more) of the power semiconductor devices 100 may be mounted to the circuit board 402 for use in a high power application, e.g., where the maximum current is in a range of 100 to 1,000 Amps and/or power losses are in a range of 100 to 1,000 Watts. The circuit board 402 may be a controller board for controlling operation of the power semiconductor devices 100. The power semiconductor devices 100 are shown as surface mount packages in FIG. 5, where there the package leads 116 are attached to the circuit board 402 by respective solder joints 404. However, the power semiconductor devices 100 instead may be through-hole mount packages, e.g., as shown in FIGS. 4A to 4C.

In each case, the power electronics assembly 400 of FIG. 5 also includes a thermal interface material 406 applied to the aluminum layer 124 of each IMS 104. The thermal interface material 406 may be a thermal tape, grease, gel, adhesive, sinter layer, dielectric pad, PCM, etc. The thermal interface material 406 may include fillers such as non-melting inorganic materials. In one embodiment, the aluminum layer 124 of each IMS 104 is thicker than the thermal interface material 406. Separately or in combination, the aluminum layer 124 of each IMS 104 has a thickness T_Al in a range of 0.5 mm to 5 mm and the thermal interface material 406 has a thickness T_TIM in a range of 100 μm to 500 μm.

The power electronics assembly 400 of FIG. 5 further includes a cooling system 408 thermally connected to each IMS 104 through the thermal interface material 406. The cooling system 408 may be an active or passive cooling system. In the case of an active cooling, the cooling system 408 may include a pump and radiator. In the case of passive cooling, the cooling system 408 may include fins or other structures for dissipating heat to the surrounding environment.

During production of the power electronics assembly 400, metallic debris 410 such as Cu (copper) and/or Al (aluminum) particles/burrs may become trapped between the cooling system 408 and one or more of the power semiconductor devices 100. However, the combined thickness (T_TIM+T_Al) of the thermal interface material 406 and the aluminum layer 124 of each IMS 104 is greater than the thickness T_D of the metallic debris 410 such that the metallic debris 410 is confined outside the organic isolation layer 126 of each IMS 104. For example, the metallic debris 410 may have a thickness T_D up to 600 μm and the combined thickness (T_TIM+T_Al) of the thermal interface material 406 and the aluminum layer 124 of each IMS 104 may be greater than 600 μm. Accordingly, the metallic debris 410 may penetrate the thermal interface material 406 and possibly even the aluminum layer 124 of at least one IMS 104 but not the organic isolation layer 126 of any IMS 104. Such a design ensures that the organic isolation layer 126 of each IMS 104 remains fully intact and uncompromised by the metallic debris 410, which in turn ensures the copper layer 122 of each IMS 104 remains electrically isolated from the cooling system 408.

Although the present disclosure is not so limited, the following numbered examples demonstrate one or more aspects of the disclosure.

Example 1. A power semiconductor device, comprising: a molded package comprising one or more power semiconductor dies embedded in a mold compound and forming part of a power electronics circuit, wherein a metallic region exposed at a topside of the molded package forms part of a primary thermal pathway for heat dissipated by the one or more power semiconductor dies during operation; and an insulated metal substrate (IMS) comprising a copper layer attached to the metallic region exposed at the topside of the molded package, an aluminum layer at an opposite side of the IMS as the copper layer, and an organic isolation layer that electrically isolates the copper layer and the aluminum layer from one another, wherein the copper layer provides no electrical rerouting for the molded package.

Example 2. The power semiconductor device of example 1, wherein the aluminum layer of the IMS has a thickness in a range of 0.5 mm to 5 mm, and wherein the organic isolation layer of the IMS has a thickness in a range of 5 μm to 250 μm.

Example 3. The power semiconductor device of example 2, wherein the copper layer of the IMS has a thickness in a range of 35 μm to 350 μm.

Example 4. The power semiconductor device of any of examples 1 through 3, wherein the molded package is a surface mount package.

Example 5. The power semiconductor device of any of examples 1 through 4, wherein the molded package is a through-hole mount package.

Example 6. The power semiconductor device of any of examples 1 through 5, further comprising a thermal interface material applied to the aluminum layer of the IMS.

Example 7. The power semiconductor device of example 6, wherein the aluminum layer of the IMS is thicker than the thermal interface material.

Example 8. The power semiconductor device of example 6, wherein the aluminum layer of the IMS has a thickness in a range of 0.5 mm to 5 mm, and wherein the thermal interface material has a thickness in a range of 100 μm to 500 μm.

Example 9. The power semiconductor device of any of examples 1 through 8, wherein the copper layer of the IMS is glued, soldered, or welded to the metallic region exposed at the topside of the molded package.

Example 10. A power electronics assembly, comprising: a circuit board; a plurality of power semiconductor devices mounted to the circuit board and each comprising: a molded package comprising one or more power semiconductor dies embedded in a mold compound and forming part of a power electronics circuit, wherein a metallic region exposed at a side of the molded package that faces away from the circuit board forms part of a primary thermal pathway for heat dissipated by the one or more power semiconductor dies during operation; and an insulated metal substrate (IMS) comprising a copper layer attached to the metallic region exposed at the side of the molded package that faces away from the circuit board, an aluminum layer at an opposite side of the IMS as the copper layer, and an organic isolation layer that electrically isolates the copper layer and the aluminum layer from one another, wherein the copper layer provides no electrical rerouting for the molded package; a thermal interface material applied to the aluminum layer of each IMS; and a cooling system thermally connected to each IMS through the thermal interface material.

Example 11. The power electronics assembly of example 10, wherein the aluminum layer of each IMS is thicker than the thermal interface material.

Example 12. The power electronics assembly of example 10, wherein the aluminum layer of each IMS has a thickness in a range of 0.5 mm to 5 mm, and wherein the thermal interface material has a thickness in a range of 100 μm to 500 μm.

Example 13. The power electronics assembly of any of examples 10 through 12, further comprising metallic debris trapped between the cooling system and one or more of the power semiconductor devices, wherein a combined thickness of the thermal interface material and the aluminum layer of each IMS is greater than a thickness of the metallic debris such that the metallic debris is confined outside the organic isolation layer of each IMS.

Example 14. The power electronics assembly of any of examples 10 through 12, further comprising metallic debris trapped between the cooling system and one or more of the power semiconductor devices and having a thickness up to 600 μm, wherein a combined thickness of the thermal interface material and the aluminum layer of each IMS is greater than 600 μm.

Example 15. The power electronics assembly of any of examples 10 through 12, further comprising metallic debris trapped between the cooling system and one or more of the power semiconductor devices, wherein the metallic debris penetrates the thermal interface material and the aluminum layer of at least one IMS but not the organic isolation layer of any IMS.

Example 16. The power electronics assembly of any of examples 10 through 15, wherein the aluminum layer of each IMS has a thickness in a range of 0.5 mm to 5 mm, and wherein the organic isolation layer of each IMS has a thickness in a range of 5 μm to 250 μm.

Example 17. The power electronics assembly of example 16, wherein the copper layer of each IMS has a thickness in a range of 35 μm to 350 μm.

Example 18. The power electronics assembly of any of examples 10 through 17, wherein each of the molded packages is surface mounted to the circuit board.

Example 19. The power electronics assembly of any of examples 10 through 17, wherein each of the molded packages is through-hole mounted to the circuit board.

Example 20. The power electronics assembly of any of examples 10 through 19, wherein for each power semiconductor device, the copper layer of the IMS is glued, soldered, or welded to the metallic region exposed at the side of the molded package that faces away from the circuit board.

Terms such as “first”, “second”, and the like, are used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to include all possible conjunctive and disjunctive combinations, unless expressly noted otherwise. For example, the expression “A and/or B” should be interpreted to mean only A, only B, or both A and B. The expression “at least one of” should be interpreted in the same manner as “and/or”, unless expressly noted otherwise. For example, the expression “at least one of A and B” should be interpreted to mean only A, only B, or both A and B.

It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A power semiconductor device, comprising:
a molded package comprising one or more power semiconductor dies embedded in a mold compound and forming part of a power electronics circuit, wherein a metallic region exposed at a topside of the molded package forms part of a primary thermal pathway for heat dissipated by the one or more power semiconductor dies during operation; and
an insulated metal substrate (IMS) comprising a copper layer attached to the metallic region exposed at the topside of the molded package, an aluminum layer at an opposite side of the IMS as the copper layer, and an organic isolation layer that electrically isolates the copper layer and the aluminum layer from one another, wherein the copper layer provides no electrical rerouting for the molded package.

2. The power semiconductor device of claim 1, wherein the aluminum layer of the IMS has a thickness in a range of 0.5 mm to 5 mm, and wherein the organic isolation layer of the IMS has a thickness in a range of 5 μm to 250 μm.

3. The power semiconductor device of claim 2, wherein the copper layer of the IMS has a thickness in a range of 35 μm to 350 μm.

4. The power semiconductor device of claim 1, wherein the molded package is a surface mount package.

5. The power semiconductor device of claim 1, wherein the molded package is a through-hole mount package.

6. The power semiconductor device of claim 1, further comprising a thermal interface material applied to the aluminum layer of the IMS.

7. The power semiconductor device of claim 6, wherein the aluminum layer of the IMS is thicker than the thermal interface material.

8. The power semiconductor device of claim 6, wherein the aluminum layer of the IMS has a thickness in a range of 0.5 mm to 5 mm, and wherein the thermal interface material has a thickness in a range of 100 μm to 500 μm.

9. The power semiconductor device of claim 1, wherein the copper layer of the IMS is glued, soldered, or welded to the metallic region exposed at the topside of the molded package.

10. A power electronics assembly, comprising:
a circuit board;
a plurality of power semiconductor devices mounted to the circuit board and each comprising:
a molded package comprising one or more power semiconductor dies embedded in a mold compound and forming part of a power electronics circuit, wherein a metallic region exposed at a side of the molded package that faces away from the circuit board forms part of a primary thermal pathway for heat dissipated by the one or more power semiconductor dies during operation; and
an insulated metal substrate (IMS) comprising a copper layer attached to the metallic region exposed at the side of the molded package that faces away from the circuit board, an aluminum layer at an opposite side of the IMS as the copper layer, and an organic isolation layer that electrically isolates the copper layer and the aluminum layer from one another, wherein the copper layer provides no electrical rerouting for the molded package;
a thermal interface material applied to the aluminum layer of each IMS; and
a cooling system thermally connected to each IMS through the thermal interface material.

11. The power electronics assembly of claim 10, wherein the aluminum layer of each IMS is thicker than the thermal interface material.

12. The power electronics assembly of claim 10, wherein the aluminum layer of each IMS has a thickness in a range of 0.5 mm to 5 mm, and wherein the thermal interface material has a thickness in a range of 100 μm to 500 μm.

13. The power electronics assembly of claim 10, further comprising metallic debris trapped between the cooling system and one or more of the power semiconductor devices, wherein a combined thickness of the thermal interface material and the aluminum layer of each IMS is greater than a thickness of the metallic debris such that the metallic debris is confined outside the organic isolation layer of each IMS.

14. The power electronics assembly of claim 10, further comprising metallic debris trapped between the cooling system and one or more of the power semiconductor devices and having a thickness up to 600 μm, wherein a combined thickness of the thermal interface material and the aluminum layer of each IMS is greater than 600 μm.

15. The power electronics assembly of claim 10, further comprising metallic debris trapped between the cooling system and one or more of the power semiconductor devices, wherein the metallic debris penetrates the thermal interface material and the aluminum layer of at least one IMS but not the organic isolation layer of any IMS.

16. The power electronics assembly of claim 10, wherein the aluminum layer of each IMS has a thickness in a range of 0.5 mm to 5 mm, and wherein the organic isolation layer of each IMS has a thickness in a range of 5 μm to 250 μm.

17. The power electronics assembly of claim 16, wherein the copper layer of each IMS has a thickness in a range of 35 μm to 350 μm.

18. The power electronics assembly of claim 10, wherein each of the molded packages is surface mounted to the circuit board.

19. The power electronics assembly of claim 10, wherein each of the molded packages is through-hole mounted to the circuit board.

20. The power electronics assembly of claim 10, wherein for each power semiconductor device, the copper layer of the IMS is glued, soldered, or welded to the metallic region exposed at the side of the molded package that faces away from the circuit board.
